(19) United States
(12) Patent Application Publication
(10) Pub. No.: US 2021/0246982 A1
(43) Pub. Date: Aug. 12, 2021

(54) Waterproof Member

(71) Applicant: SEKISUI POLYMATECH CO., LTD., Saitama (JP)

(72) Inventor: Tetsuya Togo, Saitama (JP)

(73) Assignee: SEKISUI POLYMATECH CO., LTD., Saitama (JP)

(21) Appl. No.: 16/973,154

(22) PCT Filed: Aug. 6, 2019
(86) PCT No.: PCT/JP2019/030834

§ 371 Date: Dec. 8, 2020

(30) Foreign Application Priority Data
Aug. 7, 2018 (JP) 2018-148662

(51) Int. Cl. F16J 15/10; H05K 5/02

(52) U.S. Cl. CPC F16J 15/10; H05K 5/0217

(57) ABSTRACT

Provided is a waterproof member that can prevent the waterproof member from being damaged during affixation and that can inhibit water from entering without causing air bubbles or the like to enter. A waterproof member sandwiched between a first member and a second member so as to seal between the first member and the second member includes a rigid base, a flexible contact member provided on a front surface of the rigid base, and an adhesive layer provided on a back surface of the rigid base. The front surface of the rigid base has a first region f which is a partial region of the front surface and in which the flexible contact member protrudes from a periphery thereof and a second region s that is a remaining region of the rigid base excluding the partial region and that is separated from the first region.

### TECHNICAL FIELD

The present invention relates to a waterproof member.

### BACKGROUND ART

Portable electronic devices such as cellular phones, portable audio players, digital cameras, and digital video cameras are used in daily life or for leisure activities and are thus sometimes used in a place exposed to getting wet. Thus, a waterproof function is added to such portable electronic devices so that water droplets and dust are prevented from entering the inside of the portable electronic devices. For example, Japanese Unexamined Patent Application Publication No. 2005-032752 (Patent Literature 1) or Japanese Unexamined Patent Application Publication No. 2008-288174 (Patent Literature 2) describes a configuration in which a ring-shaped waterproof member made of rubber or a thermoplastic elastomer is provided to prevent water droplets and dust from entering the inside of a housing.

### CITATION LIST

### Patent Literature

PTL 1: Japanese Unexamined Patent Application Publication No. 2005-032752

PTL 2: Japanese Unexamined Patent Application Publication No. 2008-288174

### SUMMARY OF INVENTION

### Technical Problem

In recent years, however, electronic devices have become increasingly smaller and slimmer, the load of a waterproof member applied to a housing or a substrate has been required to be kept small, and a low-hardness material has come to be used. However, if hardness is decreased and flexibility is increased, a waterproof member may easily expand and contract. Thus, there readily arises a problem that a shape-retaining property is decreased, and handleability is thereby decreased to make it difficult for the waterproof member to be attached to an electric device.

That is, the low-hardness material, which is extremely flexible, may excessively deform to be damaged, and, if the low-hardness material is hardly brought into sufficient pressure contact with an adherend such as a housing or a substrate, a pressure contact force needs to be decreased. However, if do so, air bubbles may remain between an adhesive layer and the adherend, and waterproofness may be decreased. Thus, when the low-hardness material is used, there arises a problem that, if a pressure contact force is increased, a shape may be lost, and if, conversely, a pressure contact force is decreased, air bubbles easily enter.

Accordingly, the present invention has been made in view of the related art and aims to provide a waterproof member that can prevent the waterproof member from being damaged during affixation and that can inhibit water from entering without causing air bubbles and the like to enter.

### Solution to Problem

To achieve the above-described aim, a waterproof member of an aspect of the present invention is configured as below. More specifically, in an aspect of the present invention, a waterproof member that is sandwiched between a first member and a second member so as to seal between the first member and the second member includes a rigid base, a flexible contact member provided on a front surface of the rigid base, and an adhesive layer provided on a back surface of the rigid base. The flexible contact member has a 20% compression stress of 2 to 40 kPa in a direction in which the flexible contact member is brought into pressure contact.

The waterproof member sandwiched between the first member and the second member so as to seal between the first member and the second member includes the rigid base, the flexible contact member provided on the front surface of the rigid base, and the adhesive layer provided on the back surface of the rigid base, and the flexible contact member has a 20% compression stress of 2 to 40 kPa in the direction in which the flexible contact member is brought into pressure contact. Therefore, when the waterproof member is sandwiched between the first member and the second member, the adhesive layer can surely be brought into pressure contact while the shape-maintaining property of the flexible contact member is ensured. Thus, it is possible to inhibit waterproofness from being decreased due to insufficient pressure contact of the adhesive layer and to prevent the flexible contact member from excessively deforming or being torn off due to the flexible contact member being subjected to an excessive pressure contact force.

In an aspect of the present invention, the front surface of the rigid base has a first region which is a partial region of the front surface and in which the flexible contact member protrudes from a periphery thereof and a second region that is a remaining region of the rigid base excluding the partial region and that is separated from the first region. Thus, when the waterproof member is sandwiched between the first member and the second member, the second region is pressed, and the adhesive layer can surely be brought into pressure contact.

An aspect of the present invention can have a configuration including a cushioning layer between the rigid base and the adhesive layer. Because the waterproof member includes the cushioning layer between the rigid base and the adhesive layer, the uneven distribution of the stress that sometimes occurs when the second region is pressed by the first member and the second member is suppressed, and the adhesive layer can uniformly be brought into pressure contact. Thus, the waterproof member can suitably be sandwiched between the first member and the second member, air bubbles are prevented from entering the adhesive layer, and more reliable waterproofness can be obtained.

An aspect of the present invention can have a configuration including, in the second region, a thin film layer that is made of a material identical to a material of the flexible contact member. Because the waterproof member includes, in the second region, the thin film layer made of the material identical to the material of the flexible contact member, the material that is to be the flexible contact member can be provided across the entire front surface of the rigid base. Thus, the flexible contact member and the thin film layer are integrally formed and remain fixed to the rigid base, and it is thereby possible for the flexible contact member to hardly peel off from the rigid base compared with when a thin film layer is not provided. When a thin film layer can unintentionally be obtained as a burr, time and effort for removing the burr can be saved by using the burr itself as the thin film layer, a manufacturing process is simplified, and the occurrence of defective pieces is reduced.

An aspect of the present invention can have a configuration in which, in the second region, the flexible contact member is not provided and a rigid surface that is an exposed portion of the front surface of the rigid base is provided. Because the waterproof member has the configuration in which, in the second region, the flexible contact member is not provided and the rigid surface that is the exposed portion of the front surface of the rigid base is provided, the pressure contact stress generated due to the pressure contact of the first member and the second member is to be applied, in the second region, from the rigid surface directly to the adhesive layer. Thus, the adhesive layer is securely brought into pressure contact with the second member, and it is thereby possible to prevent water from permeating from the waterproof member on the adhesive layer side.

An aspect of the present invention can have a configuration in which, as viewed in a direction in which the first member and the second member are brought into pressure contact, the flexible contact member has a ring shape, and the second region is provided on both sides of the ring shape. Because the waterproof member has the configuration in which, as viewed in the direction in which the first member and the second member are brought into pressure contact, the flexible contact member has the ring shape, and the second region is provided on both sides of the ring shape, the waterproof member can also be sandwiched by the first member and the second member on both sides of the flexible contact member, and it is thereby possible to prevent displacement of the position of the flexible contact member. Thus, the waterproof member can suitably be sandwiched between the first member and the second member, and waterproofness can surely be obtained.

An aspect of the present invention can have a configuration including a dustproof sheet on a back surface of the adhesive layer. Thus, in addition to a waterproof function, a dustproof function can be added to the waterproof member.

### Advantageous Effects of Invention

According to the waterproof member of an aspect of the present invention, the rigid base can sufficiently be brought into pressure contact, and waterproofness can be maintained without the flexible contact member being damaged.

### BRIEF DESCRIPTION OF DRAWINGS

FIG. 1 illustrates a waterproof member that is a first embodiment of the present invention: FIG. 1A is a schematic plan view, and FIG. 1B is a sectional view taken along line 1B-1B in FIG. 1A.

FIG. 2 illustrates how the waterproof member that is the first embodiment of the present invention is attached to a housing or the like of an electronic device.

FIG. 3 is a sectional view, corresponding to FIG. 1A, of a waterproof member that is Modification 1 of the first embodiment of the present invention.

FIG. 4 is a sectional view, corresponding to FIG. 1A, of a waterproof member that is a modification of the first embodiment of the present invention: FIG. 4A illustrates Modification 2, and FIG. 4B illustrates Modification 3.

FIG. 5 is a sectional view, corresponding to FIG. 1A, of a waterproof member that is Modification 4 of the first embodiment of the present invention.

FIG. 6 is a sectional view, corresponding to FIG. 1A, of a waterproof member that is a modification of the first embodiment of the present invention, and FIGS. 6A to 6E respectively illustrates Modifications 5 to 8.

FIG. 7 illustrates a waterproof member that is a second embodiment of the present invention: FIG. 7A is a schematic plan view, and FIG. 7B is a sectional view taken along line 7B-7B in FIG. 7A.

FIG. 8 illustrates how the waterproof member that is the second embodiment of the present invention is installed on a housing or the like of an electronic device: FIG. 8A is a schematic sectional view before installation, and FIG. 8B is a schematic sectional view after installation.

FIG. 9 illustrates a form in which a waterproof member is pressed and sandwiched between, for example, housings of an electronic device: FIG. 9A illustrates a state in which the waterproof member of the first embodiment of the present invention is sandwiched, and FIG. 9B illustrates a state in which a waterproof member of the related art is sandwiched.

FIG. 10 is a sectional view, corresponding to FIG. 1A, of a waterproof member that is a fourth embodiment of the present invention.

FIG. 11 illustrates a state in which the waterproof member that is the fourth embodiment of the present invention is attached to a housing or the like of an electronic device.

FIG. 12 is a sectional view, corresponding to FIG. 1A, of Modification 1 of the waterproof member that is the fourth embodiment of the present invention.

FIG. 13, corresponding to FIG. 1A, is a sectional view of Modification 2 of the waterproof member that is the fourth embodiment of the present invention.

### DESCRIPTION OF EMBODIMENTS

Further detailed description will be given based on embodiments. In each embodiment, regarding the same materials, compositions, manufacturing methods, actions, effects, and the like, overlapping description will be omitted.

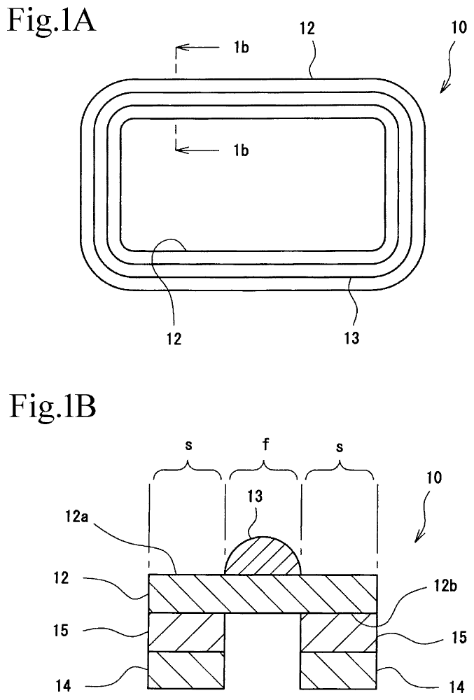

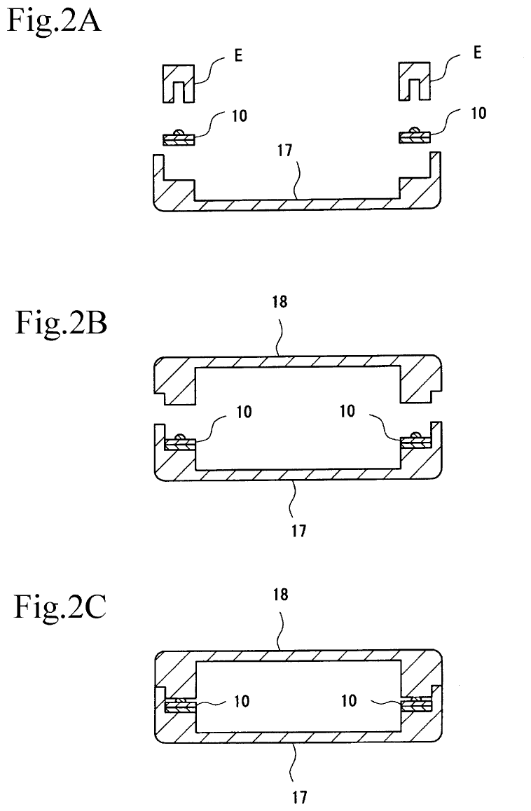

### First Embodiment [FIG. 1, FIG. 2]

A waterproof member 10 of the present embodiment will be described in detail. The waterproof member 10 is used for, for example, sealing both a front-side housing and a back-side housing of an electronic device (when one is referred to as a first member 17, the other is referred to as a second member 18) by, for example, being sandwiched between the front-side housing and the back-side housing. As FIG. 1 illustrates, the waterproof member 10 includes a rigid base 12, a flexible contact member 13 provided on a front surface 12a of the rigid base 12, an adhesive layer 14 provided on a back surface 12b of the rigid base 12, and a cushioning layer 15 provided between the rigid base 12 and the adhesive layer 14.

As a partial sectional view of FIG. 1(b) illustrates, the waterproof member 10 has a first region f that is a partial region of the front surface 12a of the rigid base 12 and in which the flexible contact member 13 protrudes from a periphery thereof and a second region s that is a remaining region of the rigid base 12 excluding the partial region and that is separated from the first region f. The first region f is a region exhibiting a function of maintaining a sealed state by the protruding flexible contact member 13 being brought into contact with the first member 17 (or the second member 18) that is a housing or the like. The second region s is a region exhibiting a function of bringing the adhesive layer 14 of the waterproof member 10 into close contact with the first member 17 (or the second member 18) by the rigid base 12 being brought into contact with the second member 18 (or the first member 17) that is a housing or the like. In the first region f, the flexible contact member 13 is layered. In the second region s, which is a region surrounding the first region f, the front surface 12a of the rigid base 12 is exposed to be a rigid surface.

When the first region f is formed to have a ring shape as viewed in the direction in which the waterproof member 10 is brought into pressure contact, that is, in plan view, the second region s is preferably provided on both sides of the ring as with the waterproof member 10 illustrated in FIG. 1(a). This is because, by providing the second region s on both sides of the ring, the waterproof member 10 can be secured, on both the inner side and the outer side of the ring, and it is thereby possible to prevent displacement of the position of the waterproof member 10 and to suitably dispose the waterproof member 10.

The aspect ratio (H/D) of the height (H) of the flexible contact member 13 to the width (D) of a basal portion thereof is set to 1 or less, and greater width is preferable. This is because, if the aspect ratio exceeds 1, the flexible contact member 13 is easily affected by water pressure due to the softness of the flexible contact member 13, and, in response to water pressure, the flexible contact member 13 may deform or topple over, or, during compression, may buckle.

The adhesive layer 14 is provided in a region that is on the back surface 12b side of the rigid base 12 and that corresponds to the second region s. This is because the waterproof member 10 is pressed substantially in the second region s, and the adhesive layer 14, by being provided in such a region, thus adheres surely to the first member 17 (or the second member 18).

The cushioning layer 15 is preferably provided so as to be layered on the adhesive layer 14. This is because the adhesive layer 14 is a portion to adhere to the first member (or the second member 18), and, if the stress holding the first member 17 and the second member 18 is non-uniformly distributed in such a portion, water leakage is easily caused in the portion.

Next, materials forming the constituents of the waterproof member 10 will be described. The material of the rigid base 12 may be, in addition to resin, metal or ceramics, and the material itself preferably does not expand and contract. A shape-retaining property is increased by the material not expanding and contracting in the in-plane direction. However, the material may have flexibility. As a resin film, for example, a polyethylene terephthalate (PET) resin, a polyethylene naphthalate (PEN) resin, a polycarbonate (PC) resin, a polymethyl methacrylate (PMMA) resin, a polyethylene (PE) resin, a polypropylene (PP) resin, a polyurethane (PU) resin, a polyamide (PA) resin, a polyether sulfone (PES) resin, a polyether ether ketone (PEEK) resin, a triacetyl cellulose (TAC) resin, a polyimide (PI) resin, a cycloolefin polymer (COP), or the like is used. The thickness of such a resin film can be, for example, 50 to 300 μm. The rigid base 12 is provided and integrated with the flexible contact member 13, and the handleability of the waterproof member 10 can thereby be increased.

For the material of the flexible contact member 13, it is possible to use various kinds and categories of soft polymeric substances having elasticity of returning to an original state when being pressed, and, in addition to a gel material, a porous material having a closed cell structure similar to a spongy state may also be used. As such a gel material, organopolysiloxane that is a two-liquid addition reaction curing type can be used. Regarding the organopolysiloxane that is the two-liquid addition reaction curing type, organopolysiloxane having a vinyl group can be used as a material A, and organopolysiloxane having a Si—H group can be used as a material B. When a mold is filled with organopolysiloxane in which such two liquids are mixed with one another and the organopolysiloxane is then heated and cured, a gel flexible contact member 13 having shape stability is formed.

The 20% compression stress of the flexible contact member 13 in the direction in which the flexible contact member 13 is brought into pressure contact is 2 to 40 kPa. The compression stress can be obtained by compressing the initial thickness of a test piece by 20% (compressing the test piece until the height becomes 80% of the initial height) and by measuring a load (N) after such a compressed state is maintained for 30 seconds. More specifically, the area (mm²) where the flexible contact member 13 and a pressure contact jig are brought into close contact when the flexible contact member 13 is compressed by 20% is measured, and load/area (N/mm²) is calculated to obtain a compression stress (kPa=10³ N/mm²).

The flexible contact member 13 having a 20% compression stress of 2 to 40 kPa is formed, depending on shape, by using a material having a type A hardness, defined by JIS K6253, of about 1 or less.

As the material of the flexible contact member 13, a material having a penetration of 60 to 190 is preferably used. This is because, when a material having a penetration of slightly more than about 60 is used, it is easy to adjust a 20% compression stress to 40 kPa or less, and, when a material of the flexible contact member has a penetration of 190 or less and even if the shape of the flexible contact member is formed into a shape of which a load is especially likely to be large, it is possible to adjust a 20% compression stress to 2 kPa or more. However, there is a concern about the strength of a flexible contact member 13 that is excessively flexible. Thus, a penetration is more preferably 60 to 130.

This is because, when the penetration of the flexible contact member 13 is in a range of 60 to 130, the flexible contact member 13 is very soft and easily comes into close contact with the first member 17 and the second member 18, and the first member 17 and the second member 18 hardly deform or are hardly damaged. On the other hand, when the penetration is less than 60, a compression load for obtaining the compressibility (about 30%) required to form a sealing structure may be increased, and the first member 17 and the second member 18 may deform or be damaged. When the penetration exceeds 130, it is difficult to handle the flexible contact member 13.

A penetration is a value obtained by measuring a surface of a test piece by using a device referred to in JIS K2220 (ISO2137) under the following test conditions. That is, the penetration is a value measured by using, instead of a ¼ scale cone, a needle having a shape prescribed by JIS K2207, with the entire weight of the needle and a needle securing tool (that is, the weight applied to the test piece) being set to 50 g, at a temperature of 25° C. It is indicated that the flexible contact member 13 becomes softer as the penetration increases. As an index of softness (hardness), other than the above-described index, there are indices of a type A and a type E defined by JIS K6253 (ISO7619), and, when the type E hardness is used, the value indicates approximately 0.

The flexible contact member 13 preferably has a compression set of 5% or less. The compression set in this case is measured in accordance with JIS K6262 (ISO815) of Japanese Industrial Standards, and more specifically, the compression set is measured under a condition of standing for 22 hours at a compressibility in a range of 50% to 80% at 70° C. When the compression set is 5% or less, a great elastic force to cause the waterproof member 10 to return to the original shape in a direction opposite to the compression direction is generated with the waterproof member 10 being compressed between the first member 17 and the second member 18. Moreover, excellent dimensional stability is achieved, and a problem such as a molding defect hardly arises.

The flexible contact member 13 preferably has a tensile strength at break, defined by JIS K6251 (ISO37), of 0.05 MPa to 0.15 MPa and a tensile elongation at break, similarly defined by JIS K6251 (ISO37), in a range of 230 to 400%. Due to having such substance characteristics, the flexible contact member 13 has a shape-retaining property and can be molded three dimensionally.

The flexible contact member 13 can have self-adhesiveness. This is because, when having a penetration of 60 to 130, the flexible contact member 13 has self-adhesiveness, unless being subjected to nonadhesive treatment. Having self-adhesiveness is preferable because it is easy to cause the flexible contact member 13 to adhere to the first member 17 and the second member 18. On the other hand, when nonadhesive treatment is performed, a waterproof member 10 without self-adhesiveness can be obtained. Examples of such nonadhesive treatment include coating with a thin film, coating with a painted layer, and coating with powder.

The waterproof function of the flexible contact member 13 preferably satisfies IPX8 of the protection class (IP Code) defined by JIS C0920 (the international standard IEC/EN60529) that is one of the standards related to the waterproofness of electronic devices. This is because, when an electronic device satisfies IPX8, whose conditions are stricter than those of IPX7, and even if the electronic device has been submerged for long time, intrusion of water into the electronic device can be avoided.

The flexible contact member 13 may be configured by layering at least two kinds of members that have different penetrations. For example, when a gel member having a penetration of 130 is layered with a thin gel member having a penetration of 60, it is possible to form a flexible contact member 13 that, while maintaining followability to the first member 17 and the second member 18 by having flexibility as high as that exhibited by a penetration of 130, can have a surface having increased strength and thus be hardly damaged.

For the adhesive layer 14, various kinds of adhesive materials can be used. Examples of an adhesive material include a silicone-based resin, a urethane-based resin, an acrylic resin, a polyester-based resin, a polyimide-based resin, a natural rubber-based adhesive material, a synthetic rubber-based adhesive material, other adhesive resins and adhesive rubbers, and an adhesive material constituted by a mixture of two or more above-described materials. Considering the case in which the first member 17 and the second member 18 are separated for repair, component replacement, or the like, a material that does not remain fixed to the first member 17 or the second member 18 is preferable. The adhesive layer 14 may be made of only an adhesive material or may be a material whose surface has an adhesive material, such as a material similar to double-sided adhesive tape.

The cushioning layer 15 is a portion to add compressibility to the waterproof member 10. When the waterproof member 10 is failed to be sandwiched between the first member 17 and the second member 18 in a preferable state, the non-uniform distribution of the stress when the waterproof member 10 is pressed is suppressed, and the adhesive layer 14 can be uniformly brought into pressure contact. The cushioning layer 15 is preferably disposed between the rigid base 12 and the adhesive layer 14. By providing the cushioning layer 15, air bubbles are prevented from remaining in the surface of the adhesive layer 14 on the rigid base 12 side, and more reliable waterproofness can be obtained. The material of the cushioning layer 15 is required to have flexibility, and a porous resin having an open-cell or closed cell structure, such as a sponge, can thus be used.

Regarding the hardness of the cushioning layer 15, a material that is harder than the flexible contact member 13 and softer than the rigid base 12 is preferably used. The hardness is preferably 5 to 90 based on the type A hardness defined by JIS K6253. When being softer than A5, the cushioning layer 15 may deform or be damaged when the adhesive layer 14 is pressurized. When the cushioning layer 15 is harder than A90 and, especially, if a device to be waterproofed has an uneven shape, the non-uniform distribution of a stress can not sufficiently be suppressed when the adhesive layer 14 is brought into pressure contact, and air bubbles may remain. The cushioning layer 15 may have a thickness with which the non-uniform distribution of the stress holding the waterproof member 10 can be suppressed when the adhesive layer 14 is brought into pressure contact.

The size of the waterproof member 10 is determined appropriately in accordance with the shapes and dimensions of the first member 17 and the second member 18 of the electronic device to which the waterproof member 10 is attached. As an example, the flexible contact member 13 may have a thickness of 0.3 to 10 mm and a width of 0.3 to 20 mm, the rigid base 12 may have a thickness of 0.01 to 0.3 mm, the cushioning layer 15 has a thickness of 0.02 to 1.0 mm, the adhesive layer 14 may have a thickness of 0.05 to 0.3 mm, the second region s, which is provided on each of both sides of the first region f, may have a width of 0.3 to 20 mm.

An example of a manufacturing method for the waterproof member 10 will be described. A resin film that is to be the rigid base 12 is disposed in a mold, and a gel polymer that is to be the flexible contact member 13 is integrally molded on a predetermined portion of a front surface of the resin film. On the other hand, a sponge sheet that is to be the cushioning layer 15 is stuck to a back surface of the resin film that is to be the rigid base 12, by using double-sided adhesive tape, and the opposite surface of the cushioning layer 15 is also layered with the double-sided adhesive tape (with mold release paper). Finally, the waterproof member 10 can be obtained by punching an outline to form a product shape. Regarding the integration of the rigid base 12 and the flexible contact member 13, after being molded, the flexible contact member 13 may also be integrated with the rigid base 12 by using the self-adhesiveness of the flexible contact member 13, or the rigid base 12 and the flexible contact member 13 may be integrated by using an adhesive, a primer, or the like.

Next, a method for attaching the waterproof member 10 to the first member 17 or the second member 18 that is a housing or the like of the electronic device will be described. As FIG. 2(a) illustrates, an attaching jig E for attaching the waterproof member 10 is placed on the surface of the waterproof member 10 on which the flexible contact member 13 is provided, and the adhesive layer 14 of the waterproof member 10 is stuck at a predetermined attachment position of one housing of the electronic device (the housing here is the back-side housing, that is, the first member 17). The other housing of the electronic device (the housing here is the front-side housing, that is, the second member 18) is positioned with respect to the previously described housing of the electronic device and stuck. In such a way, the waterproof member 10 is pressed and held between the housings on both the front side and the back side of the electronic device.

According to the waterproof member 10, by the first member 17 and the second member 18 pressing the second region s, the adhesive layer 14 can surely be brought into pressure contact, and waterproofness can be inhibited from being decreased. Moreover, an excessive pressure contact force is prevented from being applied to only the flexible contact member 13, and the flexible contact member 13 can thereby be prevented from excessively deforming or being torn off.

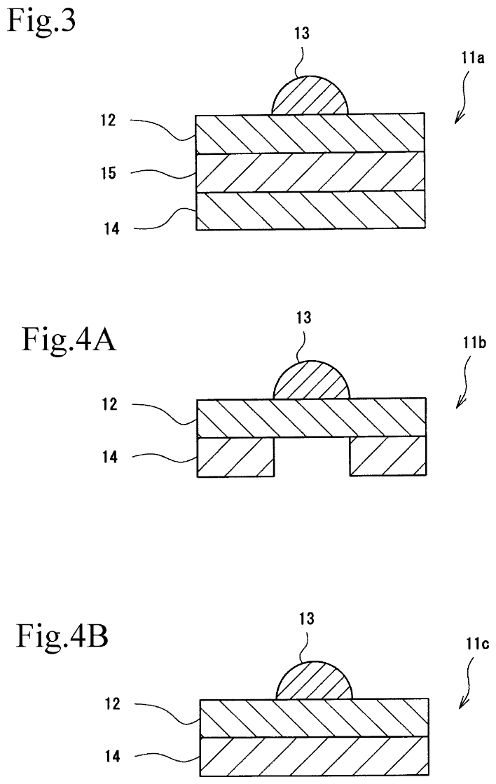

### Modification 1 [FIG. 3]

In a waterproof member 11a illustrated in FIG. 3, an adhesive layer 14 is provided across the entire back surface 12b of the rigid base 12. A cushioning layer 15 is also provided, corresponding to the adhesive layer 14, across the entire back surface 12b of the rigid base 12. When a layered structure in which the cushioning layer 15 and the adhesive layer 14 are provided on the plate-shaped rigid base 12 is manufactured in advance, regardless of the shape of the flexible contact member 13 formed on a surface of such a layered structure, the waterproof member 11a of the present embodiment can be obtained by cutting the rigid base 12 thereafter, which is preferable for manufacturing products having various shapes and can reduce time and effort related to manufacturing.

### Modification 2 [FIG. 4(a)]

A waterproof member 11b illustrated in FIG. 4(a) does not include a cushioning layer 15. Although the waterproof member 11b does not have the advantages obtained when a cushioning layer 15 is included, the waterproof member 11b has the second region s as with the waterproof member 10, a pressing force can also be received by the second region s when the first member 17 and the second member 18 are held, and it is thereby possible to avoid excessively pressing the flexible contact member 13.

### Modification 3 [FIG. 4(b)]

A waterproof member 11c illustrated in FIG. 4(b) also has a configuration without a cushioning layer 15 as with the waterproof member 11b, and the adhesive layer 14 is provided across the entire back surface of the rigid base 12. As with the waterproof member 11a illustrated in FIG. 3, when a layered structure in which the adhesive layer 14 is provided on the plate-shaped rigid base 12 is manufactured in advance, regardless of the shape of the flexible contact member 13 formed on a surface of such a layered structure, the waterproof member 11c of the present embodiment can be obtained by cutting the rigid base 12 thereafter, which is preferable for manufacturing products having various shapes and can reduce time and effort related to manufacturing. Regarding the waterproof member 11c, compared with the waterproof member 11b illustrated in FIG. 4(b), the adhesive layer 14 hardly peels off from the rigid base 12 because the adhesive layer 14 and the rigid base 12 are layered on one another in a large area.

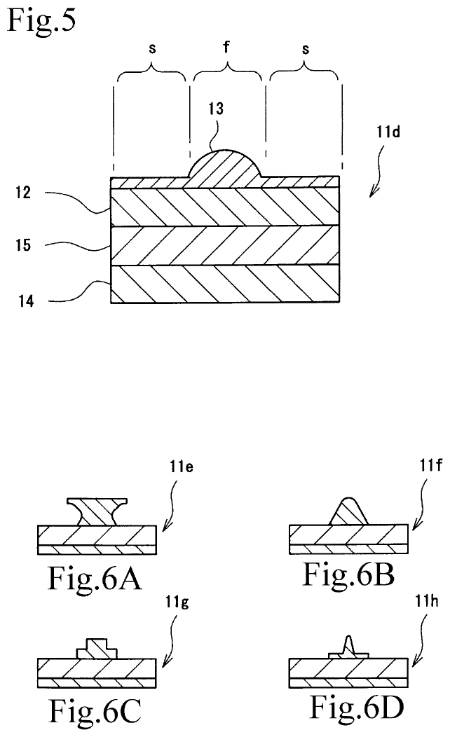

### Modification 4 [FIG. 5]

A waterproof member 11d illustrated in FIG. 5 includes, in the second region s, a layer that is constituted by the flexible contact member 13 and that can be referred to as a thin film layer 13a. That is, whereas including the flexible contact member 13 in the first region f that can clearly be separated from the second region s due to the flexible contact member 13 protruding from the second region s, the waterproof member 11d has a skin, or a burr, made of a material identical to that of the flexible contact member 13, covering the second region s. Such a portion may be a portion made of a material identical to that of the flexible contact member 13 and provided as a form of skin over the second region s intentionally in view of ease of manufacturing of the waterproof member 11d, or the portion may be a burr that is unintentionally produced together with the flexible contact member 13 that is on the first region f, during manufacturing of the waterproof member 11d.

Regarding the waterproof member 11d, as with other waterproof members 10 and 11a to 11c, by having the second region s, a pressing force applied to the waterproof member 11d can also be received by the second region s, and it is thereby possible to avoid excessively pressing the flexible contact member 13 in the first region f.

### Other Modifications [FIG. 6]

Waterproof members 11e to 11h that are modifications in which the shape of the flexible contact member 13 is changed are illustrated in FIG. 6. The flexible contact members 13, including such modifications, can have various shapes. For example, the shape can be: a ring shape or a rectangle in plan view; a semicircle, a trapezoid, a triangle, or a rectangle in sectional view; or another shape such as a combination of these shapes. Because each of the waterproof members 11e to 11h of the modifications also has, apart from the first region f in which the flexible contact member 13 is formed, the second region s in which the flexible contact member 13 is not formed, the second region s can also receive a pressing force applied to each of the waterproof members 11e to 11h, and it is thereby possible to avoid excessively pressing the flexible contact member 13 in the first region f.

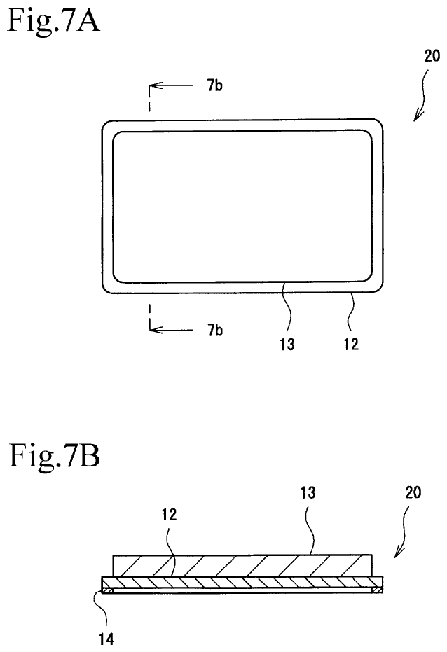

### Second Embodiment [FIG. 7]

As a plan view of FIG. 7(a) and a sectional view of FIG. 7(b) illustrate, a waterproof member 20 of the present embodiment includes a flexible contact member 13 that is provided on a portion of the rectangular rigid base 12 excluding the outer edge of the rigid base 12. In the waterproof member 20, a region in which the flexible contact member 13 is provided is a first region f, and an outer edge region of the rigid base 12 in which the flexible contact member 13 is not provided is a second region s. Although a cushioning layer 15 can be provided, the form of the present embodiment does not include a cushioning layer 15. An adhesive layer 14 is provided in an outer edge portion on the back surface 12b of the rigid base 12, which corresponds to the second region s, and has a ring shape.

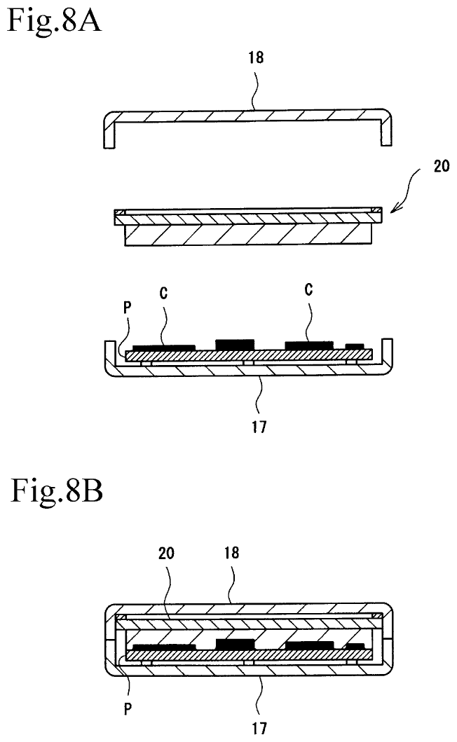

FIG. 8 illustrates one of the use forms of the waterproof member 20. As FIG. 8(a) illustrates, the waterproof member 20 is used so as to be sandwiched between one housing (a first member 17) of an electronic device incorporating a substrate P having electronic components C and the other housing (a second member 18), and, as FIG. 8(b) illustrates, when the first member 17 and the second member 18 have been assembled, the flexible contact member 13 is disposed so as to cover the electronic components C. Although the examples in which the waterproof member 10 and the like are used as a gasket are described, the waterproof member 20 not only exhibits a waterproof effect with respect to the electronic components C but also functions as a cushioning material, by covering directly the electronic components C.

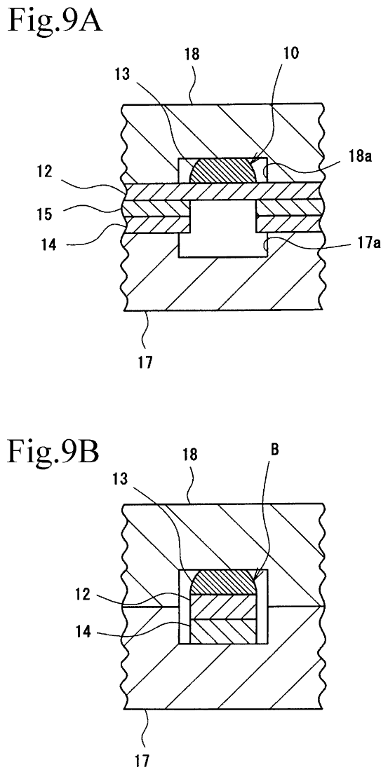

### Third Embodiment [FIG. 9]

Regarding a waterproof member 10 described in the present embodiment, which is the waterproof member 10 illustrated in the first embodiment, the use form in which the waterproof member 10 is sandwiched between a first member 17 and a second member 18 that have the shapes illustrated in FIG. 9(a) is illustrated. More specifically, to correspond to the flexible contact member 13, a recess 18a is provided to some degree in a front surface of the second member 18 with which the flexible contact member 13 comes into contact. On the other hand, although a front surface of the first member 17 may be flat, the front surface of the first member 17, as with the second member 18, has a recess 17a to some degree in FIG. 9(a). For comparison between forms, FIG. 9(b) illustrates a waterproof member B of the related art when the waterproof member B is sandwiched between the first member 17 and the second member 18 that are illustrated in FIG. 9(a).

Regarding the waterproof member B of the related art, due to a flexible contact member 13 being provided on the entire front surface of a rigid base 12, a pressing force generated by the first member 17 and the second member 18 sandwiching is applied directly to the flexible contact member 13 as FIG. 9(b) illustrates. Thus, if being excessively soft, the flexible contact member 13 cannot bear such a pressing load and may be bent or torn off. In contrast, when the waterproof member 10 of the present invention is pressed by the second member 18 having the recess 18a, as FIG. 9(a) illustrates, a pressing force generated by the first member 17 and the second member 18 sandwiching is applied to the second region s in which the flexible contact member 13 is not provided, and it is thereby possible to reduce the pressing force applied to the flexible contact member 13. Thus, even when the flexible contact member 13 is soft, the pressing load applied thereto is reduced, and the flexible contact member 13 can be prevented from being bent or torn off. Consequently, when the waterproof member 10 is used in the form of being sandwiched between the first member 17 and the second member 18 that are illustrated in FIG. 9(a), the flexible contact member 13 can be protected, and the waterproof member 10 can be pressed strongly in the second region s.

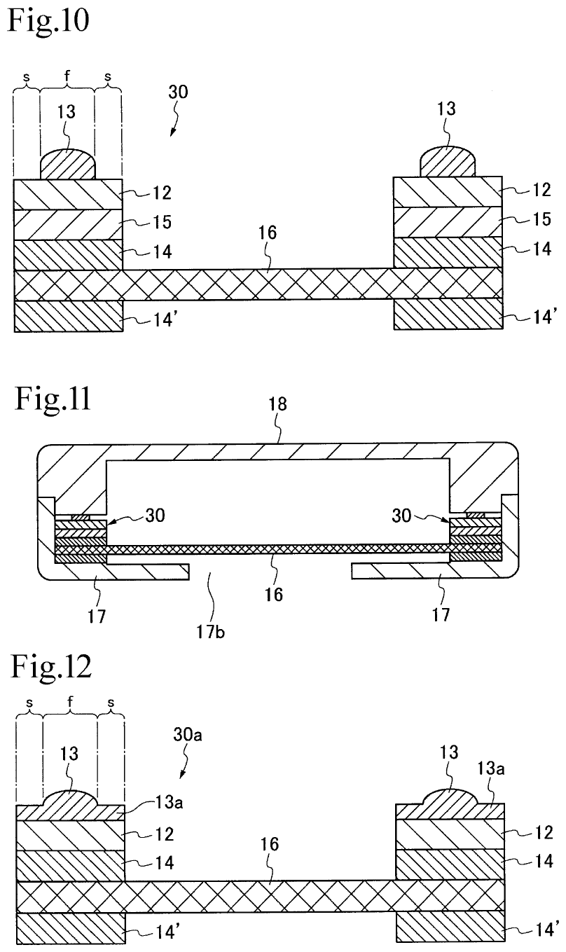

### Fourth Embodiment [FIG. 10, FIG. 11]

As FIG. 10 illustrates, a waterproof member 30 of the present embodiment has the configuration of the above-described ring-shaped waterproof member 11a (refer to FIG. 3) of Modification 1 of the first embodiment and further includes a dustproof sheet 16 having a dustproof function and disposed on a back surface of the adhesive layer 14. That is, as FIG. 10 illustrates, the waterproof member 30 includes the rigid base 12, the flexible contact member 13 provided on the front surface side of the rigid base 12, the adhesive layer 14 provided on the back surface side of the rigid base 12, the cushioning layer 15 provided between the rigid base 12 and the adhesive layer 14, and the dustproof sheet 16 provided on the back surface side of the adhesive layer 14. In addition, an adhesive layer 14′ for adhering to a first member 17 is provided on the back surface side of the dustproof sheet 16.

Thus, as FIG. 11 illustrates, when the waterproof member 30 of the present embodiment is attached so as to cover an opening 17b in the first member 17 that is a housing or the like of an electronic device such as a PC, the dustproof sheet 16 comes to exhibit a dustproof function by covering the opening 17b. The dustproof sheet 16 is preferably provided on the lower side with respect to the back surface of the rigid base 12 so that, regarding the flexible contact member 13, a shape-retaining property, a property of being in close contact with another member, and the like are ensured.

As with the above-described other waterproof members 10, 11a to 11h, and 20, in the waterproof member 30, the front surface of the rigid base 12 has the first region f that is the partial region of the front surface of the rigid base 12 and in which the flexible contact member 13 protrudes from the periphery thereof and the second region s that is the remaining region of the rigid base 12 excluding the partial region and that is separated from the first region f. Thus, when the waterproof member 30 is sandwiched between the first member 17 and the second member 18, the second region s is pressed and the adhesive layers 14 and 14′ can be surely brought into pressure contact. Consequently, it is possible to inhibit waterproofness from being decreased due to the insufficient pressure contact of the adhesive layers 14 and 14′ and to prevent the flexible contact member 13 from excessively deforming or being torn off due to the flexible contact member 13 being subjected to an excessive pressure contact force.

As described above, according to the waterproof member 30 of the present embodiment, the adhesive layer 14 can surely be brought into pressure contact by the first member 17 and the second member 18 pressing the second region s, and waterproofness can be inhibited from being decreased. Moreover, an excessive pressure contact force is prevented from being applied to only the flexible contact member 13, and the flexible contact member 13 can thereby be prevented from excessively deforming or being torn off. Furthermore, the dustproof sheet 16 covers the opening 17b of the first member 17, and it is thereby possible to exhibit a dustproof action.

In the present embodiment, as the dustproof sheet 16, a sheet-shaped member that can cause air to pass therethrough but can prevent dust from entering can be used. For example, as the dustproof sheet 16, a cloth, a net, a mesh sheet, or the like that is made of a synthetic resin or metal fibers can be used. When the dustproof sheet 16 has holes through which air passes, the diameter of the holes is preferably 100 μm or less because dust hardly passes therethrough. Moreover, to increase a property of being dustproof or waterproofness, the dustproof sheet 16 is preferably subjected to treatment such as conductivity imparting treatment or antistatic treatment, or water repellent treatment.

### Modification 1 [FIG. 12]

A waterproof member 30a illustrated in FIG. 12 has the configuration of the above-described waterproof member 30 illustrated in FIG. 10 and further includes, in the second region s, a layer that can be referred to as the thin film layer 13a and that is constituted by the flexible contact member 13 but does not include a cushioning layer 15. In the present modification, the dustproof sheet 16 is provided on the back surface side of the rigid base 12 with the adhesive layer 14 interposed therebetween, and the adhesive layer 14′ for adhering to the first member 17 that is an object to be adhered is provided on the back surface side of the dustproof sheet 16.

That is, whereas the waterproof member 30a of the present modification includes the dustproof sheet 16 provided on the back surface side of the rigid base 12 with the adhesive layer 14 interposed therebetween and includes the flexible contact member 13 in the first region f that can clearly be separated from the second region s due to the flexible contact member 13 protruding from the second region s, the waterproof member 30a has a skin or a burr made of a material identical to that of the flexible contact member 13 and covering the second region s. Such a portion may be a portion made of a material identical to that of the flexible contact member 13 and provided as a form of skin over the second region s intentionally in view of ease of manufacturing of the waterproof member 30a, or the portion may alternatively be a burr that is unintentionally produced together with the flexible contact member 13 that is on the first region f, during manufacturing of the waterproof member 30a.

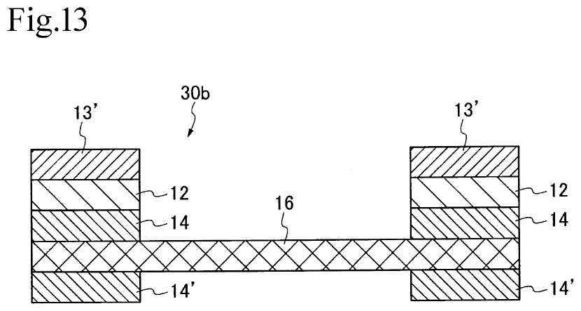

Regarding the waterproof member 30a, as with other waterproof members 10, 11a to 11h, 20, and 30, by having the second region s, a pressing force applied to the waterproof member 30a can be received by the second region s, and it is thereby possible to avoid excessively pressing the flexible contact member 13 in the first region f. Thus, the flexible contact member 13 can be prevented from excessively deforming or being torn off due to the flexible contact member 13 being subjected to an excessive pressure contact force. In the present modification, because the dustproof sheet 16 is also provided so as to cover the opening 17b (refer to FIG. 13) of the first member 17, a dustproof effect can be exhibited.

### Modification 2 [FIG. 13]

A waterproof member 30b illustrated in FIG. 13 has the configuration of the above-described waterproof member 30a illustrated in FIG. 12 but includes a flexible contact member 13′ that is flat and provided across the front surface of the rigid base 12. Although the waterproof member 30b of the present modification does not have the advantages obtained when the flexible contact member 13′ has a first region f and a second region s, the 20% compression stress of the flexible contact member 13′ in a direction in which the flexible contact member 13′ is brought into pressure contact is set to 2 to 40 kPa, and, as with the above-described other waterproof members 10, 11a to 11h, 20, 30, and 30a, it is thereby possible, while ensuring the shape-retaining property of the flexible contact member 13′, to suppress a decrease in waterproofness due to residual air bubbles between the adhesive layer 14 and the adherend. In the present modification, because the dustproof sheet 16 is also provided so as to cover the opening 17b (refer to FIG. 13) of the first member 17, a dustproof effect can be exhibited.

The above-described embodiments exemplify the present invention. It is possible, for example, to change the embodiments, to add known techniques to the embodiments, or to combine the embodiments without departing from the spirit of the present invention, and such techniques are also included in the scope of the present invention.

### REFERENCE SIGNS LIST

10, 11a to 11h, 20, 30, 30a, 30b waterproof member
12 rigid base
12a front surface (of rigid base)
12b back surface (of rigid base)
13, 13′ flexible contact member
13a thin film layer
14, 14′ adhesive layer
15 cushioning layer
f first region
s second region
16 dustproof sheet
17 first member
17a recess
17b opening
18 second member
18a recess
B waterproof member (of related art)
C electronic component
E attaching jig
P substrate

1. A waterproof member sandwiched between a first member and a second member so as to seal between the first member and the second member, the waterproof member comprising:
a rigid base;
a flexible contact member provided on a front surface of the rigid base; and
an adhesive layer provided on a back surface of the rigid base, wherein the flexible contact member has a 20% compression stress of 2 to 40 kPa in a direction in which the flexible contact member is brought into pressure contact.

2. The waterproof member according to claim 1, wherein
the front surface of the rigid base has a first region which is a partial region of the front surface and in which the flexible contact member protrudes from a periphery thereof and a second region that is a remaining region of the rigid base excluding the partial region and that is separated from the first region.

3. The waterproof member according to claim 1, further comprising:
a cushioning layer between the rigid base and the adhesive layer.

4. The waterproof member according to claim 2, further comprising:
in the second region, a thin film layer that is made of a material identical to a material of the flexible contact member.

5. The waterproof member according to claim 2, wherein
in the second region, the flexible contact member is not provided and a rigid surface that is an exposed portion of the front surface of the rigid base is provided.

6. The waterproof member according to claim 2, wherein
as viewed in a direction in which the first member and the second member are brought into pressure contact, the flexible contact member has a ring shape and the second region is provided on both sides of the ring shape.

7. The waterproof member according to claim 1, further comprising:
a dustproof sheet on a back surface of the adhesive layer.
